(19) United States
(12) Patent Application Publication
(10) Pub. No.: US 2025/0364284 A1
(43) Pub. Date: Nov. 27, 2025

(54) BUFFER CHAMBER AND SUBSTRATE PROCESSING APPARATUS INCLUDING THE CHAMBER

(71) Applicant: SEMES CO., LTD., Cheonan-si (KR)

(72) Inventors: Sang Hyeop LEE, Hwaseong-si (KR); Hee Chan KIM, Hwaseong-si (KR); Sang Oh KIM, Seoul (KR); Myung Jin LEE, Hwaseong-si (KR); Na Hyun LEE, Ansan-si (KR); Min Seong KIM, Hwaseong-si (KR)

(73) Assignee: SEMES CO., LTD., Cheonan-si (KR)

(21) Appl. No.: 19/213,459

(22) Filed: May 20, 2025

(30) Foreign Application Priority Data
May 22, 2024 (KR) 10-2024-0066629

(51) Int. Cl. H01L 21/67; H01L 21/677

(52) U.S. Cl. CPC H01L 21/67196; H01L 21/67178; H01L 21/67184; H01L 21/67225; H01L 21/67742; H01L 21/67766

(57) ABSTRACT

An objective of the present disclosure is to provide a buffer chamber that can maintain the atmosphere in a buffer unit at low humidity, and an apparatus for treating substrate that includes the buffer chamber. The present disclosure discloses substrate processing apparatus. The apparatus for treating substrates may include: a first module; a second module; and a buffer chamber disposed between the first module and the second module and temporarily keeping substrates that are transferred between the first module and the second module, wherein the buffer chamber includes: a housing providing an internal space; a supporting unit having a supporting plate, on which a substrate is placed, in the internal space; a first shutter unit formed on a first sidewall of the housing, and opening and closing a first entrance for loading and unloading substrates; and a gas supply unit supplying gas into a storage space.

### CROSS-REFERENCE TO RELATED APPLICATIONS

This application claims priority to and the benefit of Korean Patent Application No. 10-2024-0066629 filed in the Korean Intellectual Property Office on May 22, 2024, the entire contents of which are incorporated herein by reference.

### TECHNICAL FIELD

The present disclosure relates to a buffer chamber and a substrate processing apparatus that includes the buffer chamber.

### BACKGROUND ART

In general, various processes such as cleaning, deposition, photolithography, etching, and ion implantation are performed to manufacture a semiconductor device. Recently, with the higher integration of semiconductor devices, miniaturization of resist patterns has been required. In order to realize miniaturization of resist patterns, exposure processing using extreme ultraviolet (EUV) light has been proposed. Since the exposure process using EUV light requires high resolution, high etching resistance, and high sensitivity to exposure in the resist, a metal-containing resist (hereinafter referred to as “metal-containing resist”) is used as a resist.

Substrates coated with a metal-containing resist are held in a buffer unit for a predetermined time before or after each process. In this case, since metal-containing resists are sensitive to moisture, the atmosphere around substrates needs to be controlled to maintain low humidity. However, since a buffer unit has an open structure, there is a problem that it is difficult to control the atmosphere around substrates and substrates are easily exposed to moisture.

Further, even if a buffer unit is provided in a sealed form, when the buffer unit stores a plurality of substrates, if the opening degree of a shutter is not controlled, there is a problem that it is difficult to maintain the atmosphere of the buffer unit the structure becomes complicated due to a shutter driving unit for driving the shutter.

### SUMMARY OF THE INVENTION

An objective of the present disclosure is to provide a buffer chamber that can maintain the atmosphere in a buffer unit at low humidity, and substrate processing apparatus that includes the buffer chamber.

Further, an objective of the present disclosure is to provide a buffer chamber that can protect a metal-containing resist coated on a substrate, and substrate processing apparatus that includes the buffer chamber.

Further, an objective of the present disclosure is to provide a buffer chamber that enables stacking of a plurality of buffer chambers by simplifying the structure of the buffer chamber, and substrate processing apparatus that includes the buffer chamber.

Further, an objective of the present disclosure is to provide a buffer chamber that can improve processing efficiency by allowing a plurality of substrate transfer robots to approach simultaneously, and substrate processing apparatus that includes the buffer chamber.

The objectives of the present disclosure are not limited thereto and other objectives not stated herein may be clearly understood by those skilled in the art from the following description.

An exemplary embodiment of the present disclosure, the apparatus for treating substrates may include, a first module; a second module; and a buffer chamber disposed between the first module and the second module and temporarily keeping substrates that are transferred between the first module and the second module, wherein the buffer chamber includes: a housing providing an internal space; a supporting unit having a supporting plate, on which a substrate is placed, in the internal space; a first shutter unit formed on a first sidewall of the housing, and opening and closing a first entrance for loading and unloading substrates; and a gas supply unit supplying gas into a storage space.

According to an embodiment of the present disclosure, the first module is an index module, the second module is a processing module, the index module includes: a load port on which a container accommodating substrates is placed; and an index robot transferring substrates from a container placed on the load port to the processing module, and storing substrates processed in the processing module into the container placed on the load port, and the second module may include: a process chamber processing substrates; and a transfer chamber having a transfer robot that loads substrates into the process chamber or unloads substrates from the process chamber.

According to an embodiment of the present disclosure, the buffer chamber further may include a cooling unit that cools a substrate placed on the supporting plate.

According to an embodiment of the present disclosure, the first shutter unit includes: a first shutter opening and closing the first entrance; and a first shutter actuator actuating the first shutter, and the first shutter actuator may operates to open and close only a partial area of the first entrance.

According to an embodiment of the present disclosure, the first shutter unit includes: a first inner shutter; and a first outer shutter, the first inner shutter is provided in a ring shape such that a first opening is formed in a center area, the first outer shutter is installed to seal the first opening, and the first shutter may actuator independently drives the first outer shutter and the first inner shutter.

According to an embodiment of the present disclosure, the first shutter actuator is installed adjacent to the first sidewall, a plurality of buffer chambers is stacked, and the apparatus further may include a buffer robot that transfers substrates among the buffer chambers.

According to an embodiment of the present disclosure, the buffer chamber further includes a second shutter unit formed on a second sidewall of the housing, and opening and closing a second entrance for loading and unloading substrates, the second entrance faces the transfer robot, and
the first may entrance faces the buffer robot.

According to an embodiment of the present disclosure, the buffer chamber is a first buffer chamber, the buffer robot is a first buffer robot, the apparatus further includes: second buffer chambers; a second buffer robot transferring substrates among the second buffer chambers; and an interface module positioned at the rear side of the processing module and connecting the apparatus to an external device, and the second buffer chambers may be positioned at the rear side of the processing module and the interface module.

According to an embodiment of the present disclosure, the gas supply unit may include a showerhead spraying the gas to the space.

According to an embodiment of the present disclosure, the gas may be a low-humidity gas or a gas not containing moisture.

An exemplary embodiment of the present disclosure, a buffer chamber for temporarily storing substrates, the buffer chamber comprising: a housing providing an internal space; a supporting unit having a supporting plate on which a substrate is placed in the internal space; a first shutter unit formed on a first sidewall of the housing, and opening and closing a first entrance for loading and unloading substrates; and a gas supply unit supplying gas into a storage space.

According to an embodiment of the present disclosure, the apparatus may further include a cooling unit cooling a substrate on the supporting plate.

According to an embodiment of the present disclosure, the first shutter unit includes: a first shutter opening and closing the first entrance; and a first shutter actuator actuating the first shutter, and the first shutter actuator may operates to open and close only an area corresponding to the supporting plate of the first entrance.

According to an embodiment of the present disclosure, the first shutter unit includes: a first inner shutter; and a first outer shutter, the first inner shutter is provided in a ring shape such that a first opening is formed in a center area, the first outer shutter is installed to seal the first opening, and the first shutter may actuator independently drives the first outer shutter and the first inner shutter.

According to an embodiment of the present disclosure, the first shutter actuator may be installed adjacent to the first sidewall.

According to an embodiment of the present disclosure, the buffer chamber further may include a second shutter unit formed on a second sidewall of the housing, and opening and closing a second entrance for loading and unloading substrates,

An exemplary embodiment of the present disclosure, substrate processing apparatus, comprising: an index module unloading substrates from a container accommodating substrates or loading substrates into the container; a processing module processing substrates; and a buffer chamber temporarily storing substrates, wherein the index module includes: a load port on which a container accommodating substrates is placed; and an index robot transferring substrates from a container placed on the load port to the processing module, and storing substrates processed in the processing module into the container placed on the load port, wherein the processing module includes: a process chamber processing substrates; and a transfer chamber having a transfer robot that loads substrates into the process chamber or unloads substrates from the process chamber, wherein the buffer chamber further includes a cooling unit cooling a substrate on the supporting plate, wherein the first shutter unit includes: a first shutter opening and closing the first entrance; and a first shutter actuator actuating the first shutter, and the first shutter actuator is installed adjacent to the first sidewall, wherein a plurality of buffer chambers is stacked, and further includes a second shutter unit formed on a second sidewall of the housing, and opening and closing a second entrance for loading and unloading substrates, wherein the apparatus further includes a buffer robot that transfers substrates among the buffer chambers, the second entrance faces the transfer robot, and the first entrance faces the buffer robot.

According to an embodiment of the present disclosure, wherein the first shutter unit includes: a first inner shutter; and a first outer shutter, the first inner shutter is provided in a rectangular ring shape such that a first opening is formed in a center area, the first outer shutter is installed to seal the first opening, and the first shutter may actuator independently drives the first outer shutter and the first inner shutter.

According to an embodiment of the present disclosure, the buffer chamber is a first buffer chamber, the buffer robot is a first buffer robot, the apparatus further includes: second buffer chambers; a second buffer robot transferring substrates among the second buffer chambers; and an interface module positioned at the rear side of the processing module, and connecting the processing module to an exposure module performing exposure processing on substrates, and the second buffer chambers may be positioned at the rear side of the processing module and the interface module.

According to an embodiment of the present disclosure, the gas is a low-humidity gas or a gas not containing moisture, and the processing chamber may include: a first processing chamber coating a metal-containing resist onto substrates; and a second chamber performing thermal processing on substrates coated with the metal-containing resist.

According to an embodiment of the present disclosure, it is possible to create and maintain an atmosphere at low humidity in a buffer chamber.

Further, according to an embodiment of the present disclosure, it is possible to protect a metal-containing resist coated on a substrate.

Further, according to an embodiment of the present disclosure, it is possible to stack a plurality of buffer chambers by simplifying the structure of the buffer chambers.

Further, according to an embodiment of the present disclosure, it is possible to improve process efficiency because a plurality of substrate transfer robots simultaneously approaches.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a perspective view schematically showing substrate processing apparatus according to an embodiment of the present disclosure.

FIG. 2 is a cross-sectional view of substrate processing apparatus showing a coating block or a developing block of FIG. 1.

FIG. 3 is a plan view of the apparatus for treating substrates of FIG. 1.

FIG. 4 is a perspective view showing an example of a hand of a transfer robot of FIG. 3.

FIG. 5 is a plan view schematically showing an example of a thermal processing chamber of FIG. 3.

FIG. 6 is a front view of the thermal processing chamber of FIG. 5.

FIG. 7 is a perspective view of a buffer unit according to an embodiment of the present disclosure.

FIG. 8 is a perspective view of a buffer chamber according to an embodiment of the present disclosure.

FIG. 9 is a view showing the inside of the buffer chamber of FIG. 8 as viewed in direction A.

FIG. 10 is a view showing a supporting unit included in the buffer chamber of FIG. 9.

FIG. 11 is a view showing a supporting plate included in FIG. 10 and a cooling channel.

FIG. 12 is a view showing a state in which a first entrance is opened and closed by a combination of a first outer shutter and a first inner shutter of the buffer chamber of FIG. 8.

FIG. 13 is a view showing another state in which the first entrance is opened and closed by a combination of the first outer shutter and the first inner shutter of the buffer chamber of FIG. 8.

FIG. 14 is a perspective view showing a state in which plurality of buffer chambers and a plurality of buffer units are stacked on each other.

FIG. 15 is a view showing a state in which substrates are simultaneously transferred in a buffer chamber according to an embodiment of the present disclosure.

FIG. 16 is a perspective view showing a buffer chamber according to another embodiment of the present disclosure.

FIG. 17 is a view showing substrate processing apparatus according to another embodiment of the present disclosure.

FIG. 18 is a perspective view showing a buffer chamber according to another embodiment of the present disclosure.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

The equipment of this embodiment is described with an example of being used for performing a photolithography process on substrates such as a semiconductor wafer or a flat panel display.

An apparatus of processing substrates of the present disclosure includes a plurality of modules. An apparatus of processing substrates of the present disclosure may include a first module, a second module, and a third module. The first module, the second module, and the third module perform separate functions. The first module, the second module, and the third module may be sequentially connected. According to an embodiment, the first module is an index module 100. The second module is a processing module 300. Further, the third module is an interface module 600. However, the present disclosure is not limited thereto and, in the apparatus for treating substrates of the present disclosure, a new module may be connected or any one of a plurality of modules may be omitted. Hereafter, an embodiment of the apparatus for treating substrates according to the present disclosure is described with an example in which the first module is an index module 100, the second module is a processing module 300, and the third module is an interface module 600.

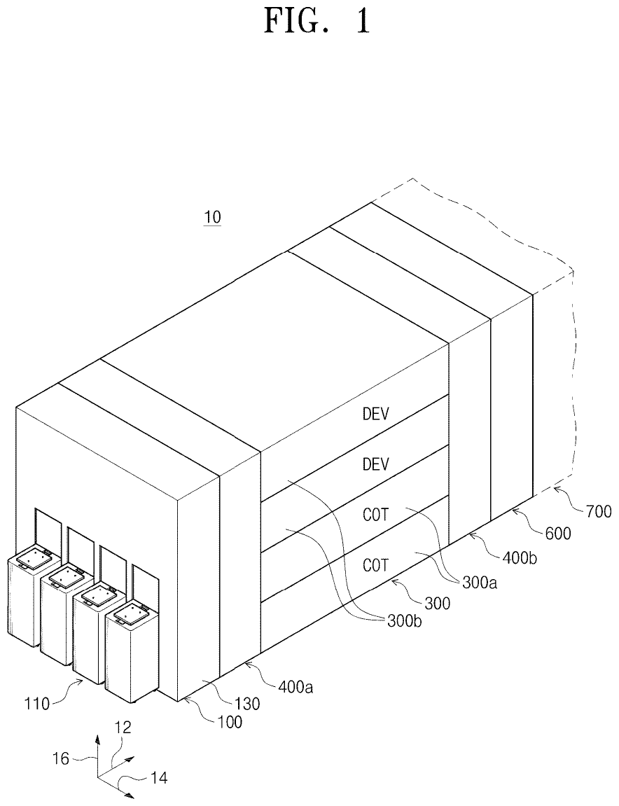

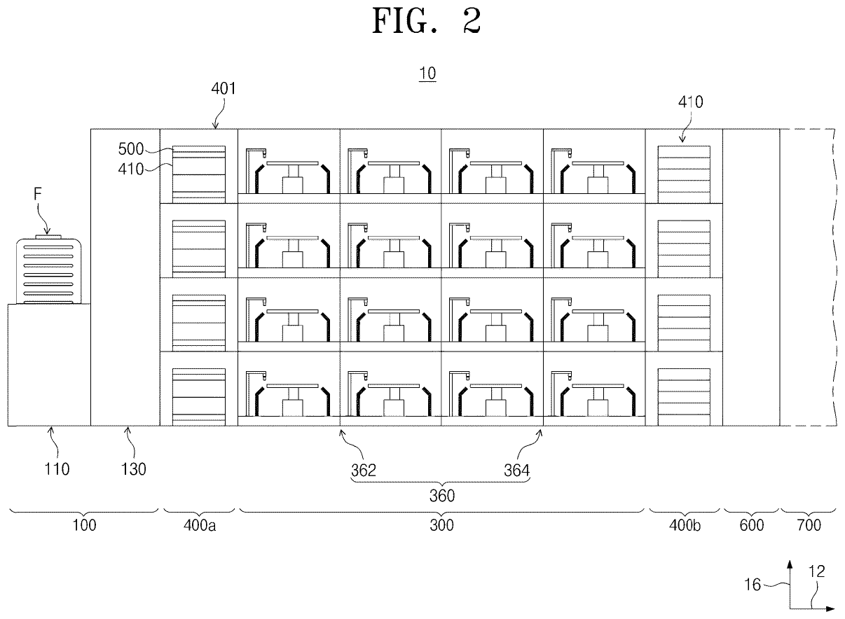

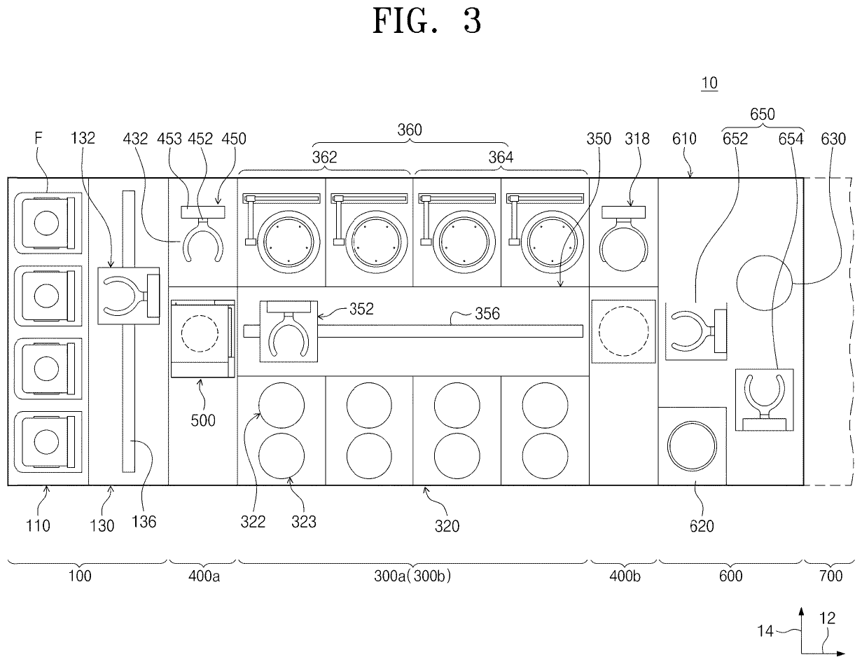

FIG. 1 is a perspective view schematically showing an apparatus of processing substrates according to an embodiment of the present disclosure, FIG. 2 is a cross-sectional view of an apparatus of processing substrates showing a coating block or a developing block of FIG. 1, and FIG. 3 is a plan view of the apparatus for treating substrates of FIG. 1.

Referring to FIG. 1 to FIG. 3, an apparatus 10 for treating substrates according to an embodiment of the present disclosure may include an index module 100, a processing module 300, a buffer module 400, and an interface module 600. Hereafter, the direction in which the index module 100, the processing module 300, the buffer module 400a, 400b, and the interface module 600 are arranged is referred to as a first direction 12, a direction perpendicular to the first direction 12 when seen from above is referred to as a second direction 14, and a direction perpendicular to both of the first direction 12 and the second direction 14 is defined as a third direction 16.

The index module 100 transfers substrates W to the processing module 300 from containers F accommodating the substrates W and stores the substrates W processed at the processing module 300 into the containers F. The longitudinal direction of the index module 100 is provided in the second direction 14. The index module 100 has a load port 110 and an index frame 130. The load port 110 is positioned at the opposite side to the processing module 300 with the index frame 130 therebetween. The container F accommodating substrates W is placed in the load port 110. A plurality of load ports 110 may be provided and the plurality of load ports 110 may be disposed in the second direction 14.

The container F may be a container F for sealing such as a Front Open Unified Pod (FOUP). The container F may be placed onto the load port 110 by a worker or a conveying device (not shown) such as an overhead transfer, an overhead conveyor, or an automatic guided vehicle.

An index robot 132 is provided in the index frame 130. A guide rail 136 of which the longitudinal direction is provided in the second direction 14 is provided in the index frame 14 and the index robot 132 may be provided to be movable on the guide rail 136. The index robot 132 includes a hand on which substrates W are placed and the hand may be provided to be able to move forward and backward, rotate around the third direction 16, and move in the third direction 16.

The processing module 300 can perform a coating process and a developing process on substrates W. The processing module 300 can receive substrates W accommodated in the containers F and perform substrate processing. The processing module 300 has a coating block 300a and a developing block 300b. The coating block 300a performs a coating process on the substrates W, and the developing block 300b performs a developing process on the substrates W. A plurality of coating blocks 300a is provided and they are stacked on each other. A plurality of developing blocks 300a is provided and they are stacked on each other. According to an embodiment, two coating blocks 300a and two developing blocks 300b are provided, respectively. The coating blocks 300a may be disposed under the developing blocks 300b. According to an embodiment, two coating blocks 300a performs the same process and may be provided with the same structure. Further, two developing blocks 300a performs the same process and may be provided with the same structure.

Referring to FIG. 3, the coating block 300a includes a thermal processing chamber 320, a transfer chamber 350, and a liquid processing chamber 360.

The thermal processing chamber 320 performs a thermal processing on substrates W. The thermal processing may include a cooling process and a heating process. The liquid processing chamber 360 forms a liquid film by supplying liquid onto substrates W. The liquid film may be a photoresist film or an anti-reflection film. According to an example, the photoresist film may be a metal-containing resist film. The transfer chamber 350 transfers substrates W among the thermal processing chamber 30, the liquid process chamber 360, and the buffer chamber 500.

The longitudinal direction of the transfer chamber 350 is provided in parallel with the first direction 12. The transfer chamber 350 has a transfer robot 352. The transfer robot 352 transfers substrates W among the thermal processing chamber 30, the liquid process chamber 360, and the buffer module 400. According to an embodiment, the transfer robot 352 includes a hand on which substrates W are placed and the hand may be provided to be able to move forward and backward, rotate around the third direction 16, and move in the third direction 16. A guide rail 356 of which the longitudinal direction is provided in parallel with the first direction 12 is provided in the transfer chamber 350 and the transfer robot 352 may be provided to be movable on the guide rail 356.

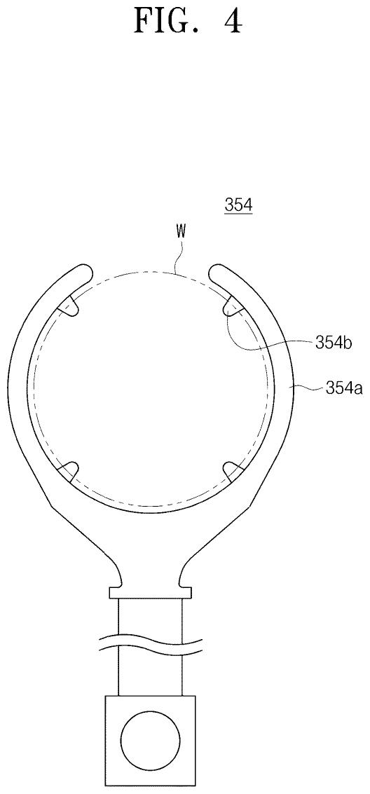

FIG. 4 is a perspective view showing an example of a hand of a transfer robot of FIG. 3. Referring to FIG. 4, the hand 354 has a base 354a and a supporting projection 354b. The base 354a may have a partially cut-off annular ring shape. The base 354a has an inner diameter larger than the diameter of substrates W. The supporting projection 354b extends inward from the base 354a. A plurality of supporting projections 354b is provided and supporting the edge of a substrate W. According to an embodiment, four support projections 354b may be provided with regular intervals.

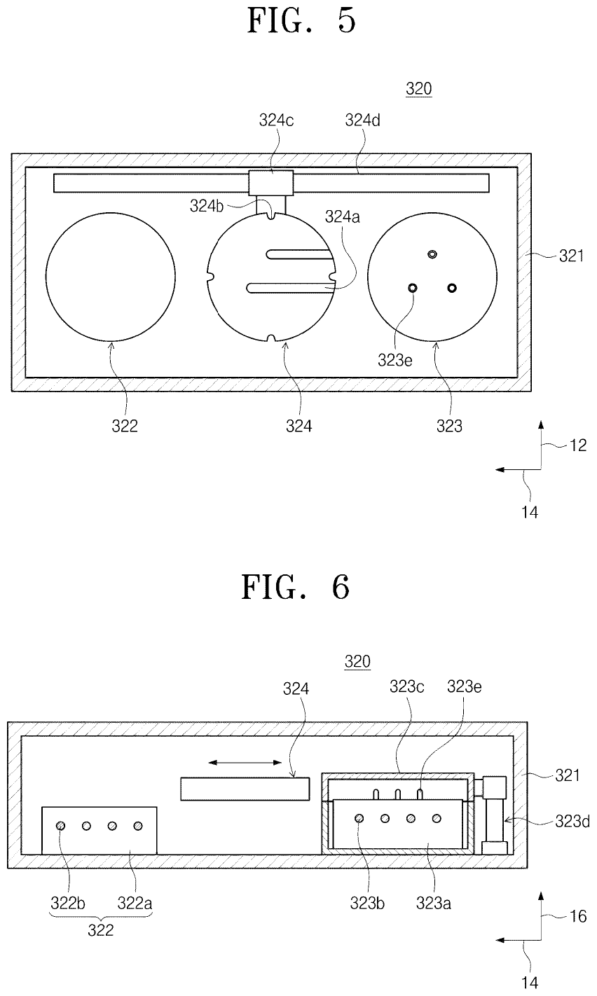

FIG. 5 is a plan view schematically showing an example of a thermal processing chamber of FIG. 3 and FIG. 6 is a front view of the thermal processing chamber of FIG. 5.

Referring to FIG. 5 and FIG. 6, the thermal processing chamber 320 includes a housing 321, a cooling member 322, a heating unit 323, and a transfer plate 324.

The housing 321 is provided substantially in a rectangular parallelepiped shape. A substrate loading/unloading port (not shown) through which substrates W are loaded and unloaded is formed on a sidewall of the housing 321. The loading/unloading port may be maintained open. A door (not shown) may be provided to selectively open/close the loading/unloading port. The cooling member 322, the heating unit 323, and the transfer plate 324 are provided in the housing 321. The cooling member 322 and the heating unit 323 are arranged in the second direction 14. According to an embodiment, the cooling member 322 may be positioned closer to the transfer chamber 350 than the heating unit 323.

The cooling member 322 has a cooling plate 322a. The cooling plate 322a may have a substantially circular shape when viewed from above. The cooling plate 322a has cooling members 322b. According to an embodiment, the cooling members 322b may be formed in the cooling plate 322a and may be provided as channels for flow of a cooling fluid.

The heating unit 323 includes a heating plate 323a, a cover 323c, and a heater 323b. The heating plate 323a has a substantially circular shape when viewed from above. The heating plate 323a has a larger diameter than substrates W. The heaters 323b are installed in the heating plate 323a. The heater 323b may be provided as a heat-generating resistor to which current is applied. The heating plate 323 is provided with the lift pins 533 that can be driven in the vertical direction in the third direction 16. The lift pins 323e receive a substrate W from a transfer device outside the heating unit 323, place it onto the heating plate 323a, or lift a substrate W from the heating plate 323a and transfer it to the transfer device outside the heating unit 323. According to an embodiment, three lift pins 323 may be provided. The cover 323c is positioned over the heating plate 323a. The cover 323c provides a heating space, in which substrates W are heated, by combining with the heating plate 323a. The cover 323c is moved in the vertical direction by an actuator 323d. When the cover 323c is moved in the third direction 16, the transfer plate can load or unload a substrate W into or out of the heating space.

The transfer plate 324 is provided substantially in a disc shape and may have a diameter corresponding to substrates W. Notches 324b are formed on the edge of the transfer plate 324. The notches 324b may have a shape corresponding to the projections 354b formed on the hand 354 of the transfer robot 352 described above. Further, the notches 324b are provided with a number corresponding to the projections 354b formed on the hand 354 and are formed at positions corresponding to the projections 354b. When the vertical positions of the hand 354 and the transfer plate 324 are changed in the state in which the hand 354 and the transfer plate 324 are aligned in the vertical direction, a substrate is transferred between the hand 354 and the transfer plate 324. The transfer plate 324 is mounted on the guide rail 324d and can be moved along the guide rail 324d by an actuator 324c. A plurality of slit-shaped guide grooves 324a is formed on the transfer plate 324. The guide grooves 324a extend from the edge of the transfer plate 324 to the inside of the transfer plate 324. The longitudinal direction of the guide groove 324a is provided in the second direction 14, and the guide grooves 324a are spaced apart from each other in the first direction 12. The guide grooves 324a prevent interference between the transfer plate 324 and the lift pin 323e when a substrate W is transferred between the transfer plate 324 and the heating unit 323.

A substrate W is cooled while the transfer plate 324 on which the substrate W is placed is in contact with the cooling plate 322a. The transfer plate 324 is made of a material having high thermal conductivity to ensure effective heat transfer between the cooling plate 322a and substrates W. According to an embodiment, the transfer plate 324 may be made of metal.

The heating unit 323 provided in some thermal processing chambers 320 among the thermal processing chambers 320 can supply gas during the heating of substrates W, thereby being able to improve the adhesion of a photoresist on the substrates. According to an example, the gas may be hexamethyldisilane (HMDS) gas.

A plurality of liquid processing chambers 360 is provided. Some of the liquid treatment chambers 360 may be stacked on each other. The liquid processing chambers 360 are disposed at a side of the transfer chamber 350. The liquid processing chambers 360 are arranged side by side in the first direction 12. Some of the liquid processing chambers 360 are provided at positions adjacent to the index module 100. Hereafter, the liquid processing chambers 360 positioned adjacent to the index module 100 are referred to as the front liquid processing chambers 362. The others of the liquid processing chambers 360 are provided at positions adjacent to the interface module 600. Hereafter, the liquid processing chambers 364 positioned adjacent to the interface module 600 are referred to as the rear liquid processing chambers 364.

The front liquid processing chambers 62 coat a first liquid onto substrates W, and the rear liquid processing chambers 364 coat a second liquid onto substrates W. The first liquid and the second liquid may be different types of liquid. According to an embodiment, the first liquid is an anti-reflection film and the second liquid is a photoresist. A photoresist may be coated on substrates W coated with an anti-reflection film. Selectively, the first liquid may be a photoresist and the second liquid may be an anti-reflection film. In this case, an anti-reflection film may be coated on substrates W coated with a photoresist. Selectively, the first liquid and the second liquid may be the same type of liquid and they may be both photoresists. According to an example, a photoresist may be a metal-containing resist.

The developing block 300b has the same structure as the coating block 300a, and the liquid processing chamber provided in the developing block 300b supplies a developing solution onto substrates.

The interface module 600 connects the apparatus for 10 treating substrates with an exposure module 700. The interface module 600 includes an interface frame 610, an auxiliary process chamber 620, an interface buffer 630, and an interface robot 650.

An air fan filter unit that generates a downward airflow inside may be provided at the upper end of the interface frame 610. The auxiliary process chamber 620, the interface buffer 630, and the interface robot 650 are disposed inside the interface frame 610. The auxiliary process chamber 620 may perform a predetermined auxiliary process before a substrate W, on which a process has been completed in the coating block 300a, is transferred to the exposure module 700. Selectively, the auxiliary process chamber 620 may perform a predetermined auxiliary process before a substrate W, on which a process has been completed in the exposure module 700, is transferred to the developing block 300b. According to an example, the auxiliary process may be an edge exposure process that exposes the edge region of substrates W, a top-side cleaning process that cleans the top side of substrates W, or a bottom-side cleaning process that cleans the bottom side of substrates W. A plurality of auxiliary process chambers 620 may be provided and they may be stacked on each other. All of the auxiliary process chambers 620 may perform the same process. Selectively, some of the auxiliary process chambers 620 may perform different processes.

The interface buffer 630 provides a space in which substrates W that are transferred among the coating block 300a, the auxiliary process chamber 620, the exposure module 700, and the developing block 300b temporarily stays during transfer. A plurality of interface buffers 630 may be provided and they may be stacked on each other.

According to an example, the auxiliary process chamber 620 may be disposed on one side of a longitudinal extension line from the transfer chamber 350, and the interface buffer 630 may be disposed on the opposite side.

The interface robot 650 transfers substrates W among the coating block 300a, the auxiliary process chamber 620, the exposure module 700, and the developing block 300b. The interface robot 650 may have a transfer hand for transferring substrates W. The interface robot 650 may be provided as a single robot or a plurality of robots. According to an example, the interface robot 650 includes a first robot 652 and a second robot 654.: The first robot 652 may transfer substrates W among the rear buffer 400b, the auxiliary process chamber 620, and the interface buffer 630, and the second robot 654 may transfer substrates W between the interface buffer 630 and the exposure module 700. Further, the second robot 654 may transfer substrates W between the interface buffer 630 and the developing block 300b.

The first robot 652 and the second robot 654 each include a hand on which substrates W are placed and the hands may be provided to be able to rotate around an axis parallel with the third direction 16 and move in the third direction 16.

The hands of the index robot 132, the first robot 652, and the second robot 654 may all be provided in the same shape as the hand 354 of the transfer robot 352. Selectively, the hand of the robot that exchanges substrates W with the transfer plate 324 of the thermal processing chamber may be provided in the same shape as the hand 354 of the transfer robot 352, while the hands of the other robots may be provided in a shape different from this.

According to an embodiment, the transfer robot 352 provided in the coating block 300a and the developing block 300b can directly exchange substrates W with the transfer plate 324 positioned in the thermal processing chamber 320.

A plurality of buffer modules 400a and 400b is provided. Some of the plurality of buffer modules 400a and 400b are disposed between the index module 100 and the processing module 300. Hereafter, the buffer modules are referred to as front buffers 400a. A plurality of front buffers 400a is provided and they are stacked on each other in the vertical direction. The others of the plurality of buffer modules 400a and 400b are disposed between the processing module 300 and the interface module 600. Hereafter, these buffer modules are referred to rear buffers 400b. A plurality of rear buffers 400b is provided and they are stacked on each other in the vertical direction. The front buffers 400a and the rear buffers 400b each temporarily keep a plurality of substrates W. The substrates W kept in the front buffers 400a are loaded or unloaded by the index robot 132 and the buffer robot 450 to be described below. The substrates W kept in the rear buffers are loaded or unloaded by the transfer robot 352 and the interface robot 650.

Hereafter, the buffer modules 400a and 400b are described on the basis of the front buffer 400a. The front buffer 400a includes a frame 401, a buffer unit 410, a buffer robot 450, and a buffer chamber 500. The frame 401 may be provided in a rectangular parallelepiped shape with a hollow interior. The frame 401 is disposed between the index module 100 and the processing module 300. The buffer unit 410 and the buffer robot 450 are provided inside the frame 401.

The buffer robot 450 conveys substrates W. The buffer robot 450 transfers substrates W from the buffer unit 410 to the buffer chamber 500 to be described below, or conveys substrates W from the buffer chamber 500 to the buffer unit 410. The buffer robot 450 is positioned inside the buffer module 400. The buffer robot 450 is positioned on a side of the buffer unit 410. The buffer robot 450 is provided to be opposite to the second side 414. The buffer robot 450 can transfer substrates through the second side 414. The buffer robot 450 includes a hand 451, an arm 452, and a support 453. The hand 451 is fixedly installed on the arm 452. The arm 452 is provided as a stretchable structure so that the hand 451 can move in the second direction 14. However, the arm is not limited thereto and may be provided such that the hand can move in the direction between the second direction 14 and the first direction 12. The arm 452 is coupled to the support 453 to be straightly movable in the third direction 16 along the support 453. The support 453 has a length extending from a position corresponding to a first buffer chamber 500-1 to be described below to a position corresponding to a fourth buffer chamber 500-4. The support 453 may further extend upward or downward. The buffer robot 450 may be provided such that the hand 451 is driven only in two axes along the second direction 14 and the third direction 16.

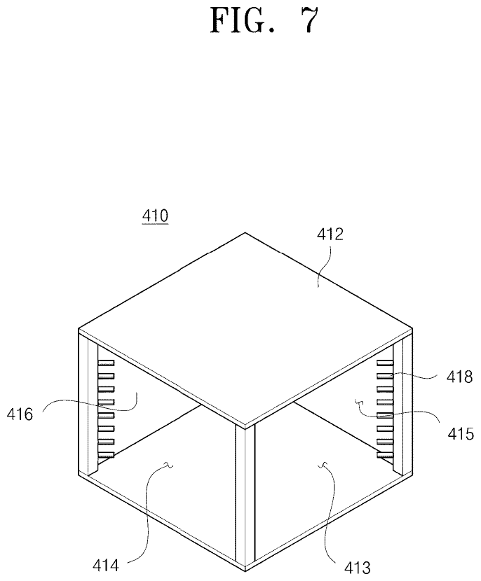

FIG. 7 is a perspective view of a buffer unit according to an embodiment of the present disclosure. Referring to FIG. 7, the buffer unit includes a housing 412 and a support 418.

The housing 412 has an empty space therein. The housing 412 has substantially in a rectangular parallelepiped shape. The housing 412 is positioned inside the frame 401 of the front buffer 400a. The housing 412 has open sides. According to an example, the housing includes a first side 413, a second side 414, a third side 415, and a fourth side 416, and the first side 413, the second side 414, and the third side 415 may be open. The first side 413 faces the index robot 132. The second side 414 faces the buffer robot 450. The third side 415 is the opposite side of the second side 414. The open sides of the housing 412 are provided as passages for loading and unloading substrates W. The support 418 for supporting substrates W is installed in the housing 412. A plurality of supports 418 may be provided. The supports 418 may be spaced apart at regular intervals. According to an example, eight supports 418 are provided. According to an example, the supports 418 are provided in the form of slots and may be installed on pillars of the housing 412. Further, the supports 418 may be installed on the fourth side 416. However, the present disclosure is not limited thereto, and it is sufficient if the supports 418 are formed on the first side 413, the second side 414, or the third side 415 so that the robots 132, 352, and 450 can load and unload substrates W.

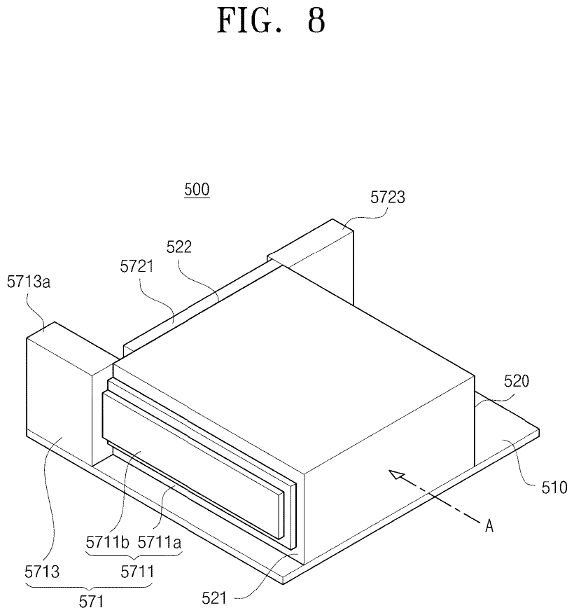

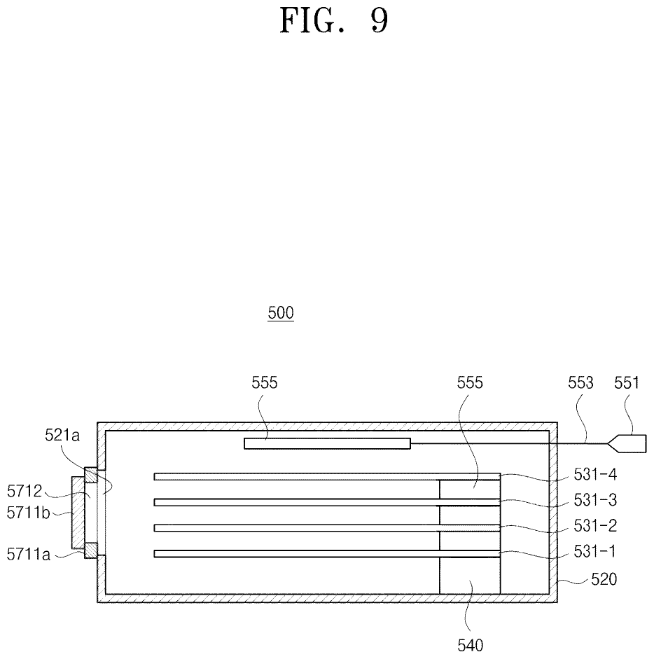

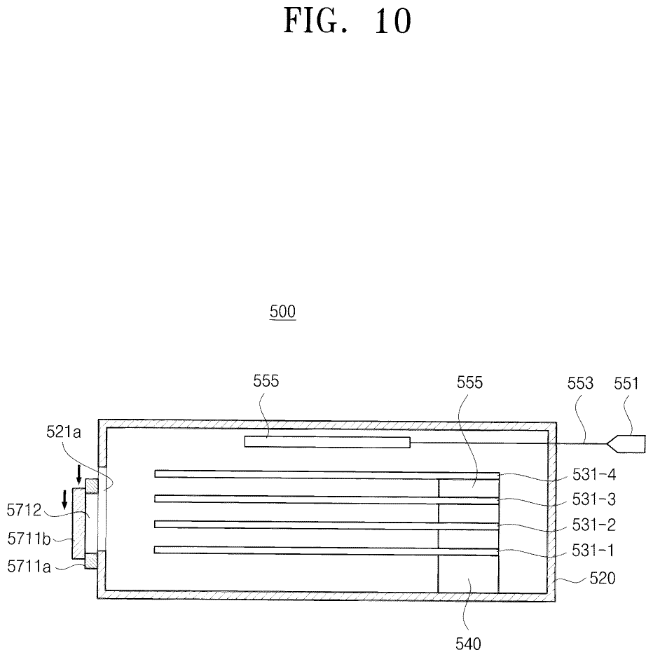

The buffer chamber 500 temporarily keeps substrates W. FIG. 8 is a perspective view of a buffer chamber according to an embodiment of the present disclosure and FIG. 9 is a view showing the inside of the buffer chamber of FIG. 8 as viewed in direction A. Referring to FIG. 8 and FIG. 9, the buffer chamber 500 includes a bottom, a housing 520, a supporting unit 530, a gas supply unit 550, a shutter unit 570, and an exhaust unit 590.

The bottom 510 provides the base of the buffer chamber 500. The housing 520 and the shutter unit 571 to be described below are installed on the bottom 510.

The housing 520 provides an internal space. The housing 520 seals the internal space. The housing 520 may be provided in a polyhedral shape. The housing 520 may be provided in a hexahedral shape. The housing 520 includes a first sidewall 521 and a second sidewall 522. According to an example, the first sidewall 521 may be a wall facing the buffer robot 450. Further, the second sidewall 522 may be a wall adjacent to the transfer chamber 350. The second sidewall 522 may be a wall facing the transfer robot 352. The first sidewall 521 and the second sidewall 522 may be walls adjacent to each other. A first entrance 521a may be formed in the first sidewall 521. A second entrance 522a may be formed in the second sidewall 522. Substrate W can be loaded and unloaded into and out of the housing 520 through the first entrance 521a and the second entrance 522a. The first entrance 521a and the second entrance 522a may be respectively opened and closed by a first shutter 5711 and a second shutter 5721 to be described below. The first opening 410 may be provided in a rectangular shape. The horizontal length of the first entrance 521a is greater than the diameter of substrates W. The horizontal length of the first entrance 521a is set such that the transfer robot 352 can enter the housing without interference. The vertical length of the first entrance 521a is set such that substrates W can be loaded onto or unloaded from the lowermost and uppermost supporting plates 531 among a plurality of supporting plates. However, the present disclosure is not limited thereto, and the size and shape may be sufficient as long as substrates W can be loaded and unloaded and the opening can be sealed by the first shutter 5711. The second entrance 522a may be provided in the same manner as the first entrance 521a.

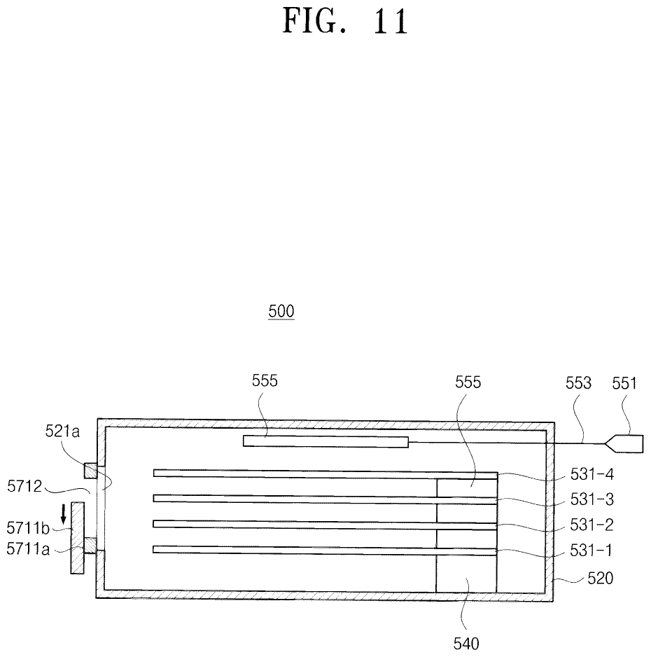

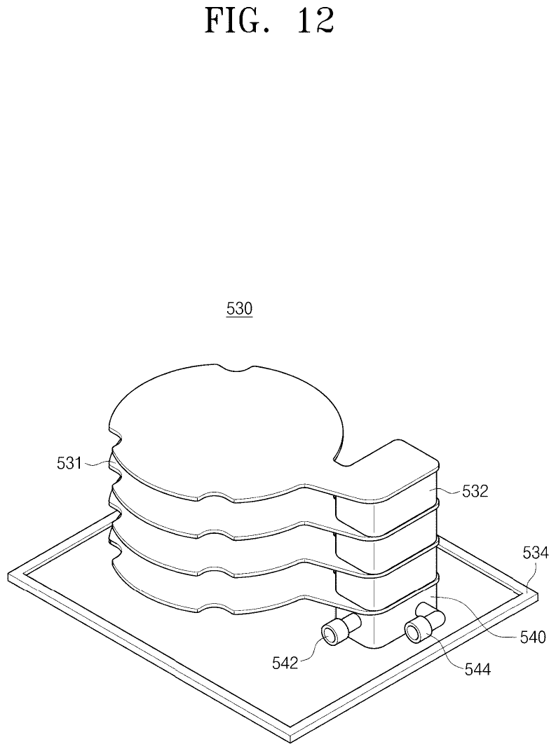

FIG. 10 is a view showing a supporting unit included in the buffer chamber of FIG. 9 and FIG. 11 is a view showing a supporting plate included in FIG. 10 and a cooling channel.

The supporting unit 530 supports substrates W in the internal space. The supporting unit 530 includes a supporting plate 531 and a connection block 532. A plurality of supporting plates 5331 is provided. According to an embodiment, four supporting plates 531 may be provided. Hereafter, four supporting plates 531-1, 531-2, 531-3, and 531-4 are described as an example. The supporting plates 531 are arranged to be stacked in the vertical direction. The supporting plates 531 may be made of aluminum. The connection block 532 is positioned between the supporting plates 531. The supporting plates 531 are spaced apart by the connection block 532. Each of the supporting plates 531 is fixedly coupled to the connection block 532. The supporting plates 531 may be provided with the same size. The supporting plates 531 may be spaced apart from each other at the same height. A cooling channel 5311 through which a cooling fluid flows is formed inside the supporting plates 531.

The cooling channel 5311 is formed inside the supporting plates 531. The cooling channel 5311 is provided as a passage through which a cooling fluid flows. A plurality of cooling channels 5311 is provided. The cooling channel 5311 includes a first channel 5311a that extends outward and a second channel 5311b that extends in the opposite direction of the outward direction, i.e., inward. The outward direction may be the direction extending from the center area toward the edge area of the supporting plate 531. The inward direction may be the direction extending from the edge area toward the center area of the supporting plate 531. The cooling fluid may be provided as a coolant.

The first channel 5311a and the second channel 5311b are provided adjacent to each other. The first channel 5311a and the second channel 5311b may be provided in the same plane within the supporting plate 531. The first channel 5311a and the second channel 5311b may be arranged in a spiral pattern.

The connection block 532 is positioned between each of the supporting plates 531, respectively. The connection block 532 ensures that adjacent supporting plates 531 are spaced apart in the vertical direction. A plurality of connection blocks 532 may be provided each substantially in a rectangular parallelepiped shape. The connection blocks 532 are stacked on top of each other.

The base block 540 supports the lowermost supporting plate 531. A supporting panel 534 is positioned under the base block 540. The supporting panel 534 supports the base block 540. The base block 540 includes an intake port 542, an exhaust port 544, a cooling fluid supply channel 543, and a cooling fluid return channel 545.

The intake port 542 receives a cooling fluid from the outside and supplies it to the cooling fluid supply channel 543. The intake port 542 is positioned on one side of the base block 540.

The exhaust port 544 discharges a cooling fluid from the cooling fluid return channel 545 to the outside. The exhaust port 544 is positioned on one side of the base block 540.

The sides of the base block 540, where the intake port 542 and exhaust port 544 are provided, may be surfaces perpendicular to each other. The intake port 542 and the exhaust port 544 can be provided at the same height from the supporting panel 534.

The cooling fluid supply channel 543 is provided inside the base block 540 and the connection block 532. The cooling fluid supply channel 543 allows cooling fluid supplied from the intake port 542 to be supplied to the supporting plates 531. One side of the cooling fluid supply channel 543 is connected to the intake port 542, and the other side branches into the inlets of the first channel 5311a and the second channel 5311b formed inside each supporting plate 531.

The cooling fluid return channel 545 is provided inside the base block 540 and the connection block 532. The cooling fluid return channel 545 allows cooling fluid discharged from the supporting plate 531 to be discharged to the exhaust port 544. One side of the cooling fluid return channel 545 is connected to the outlets of the first channel 5311a and the second channel 5311b formed inside each supporting plate 531, and the other side is connected to the exhaust port 544. The cooling fluid return channel 545 and the cooling fluid supply channel 543 may be provided parallel to each other.

Referring to FIG. 8 and FIG. 9 again, the gas supply unit 550 supplies gas into the internal space of the housing 520. The gas supply unit 550 includes a gas source 551, a gas supply line 553, and a showerhead 555. The gas source 551 stores and supplies gas. The gas may be a low-humidity gas. According to an example, the gas may be a dry gas (dry air) or a gas including nitrogen. The showerhead 555 may be provided in a disk shape. The diameter of the showerhead 555 may be smaller than the diameter of substrates W. A plurality of injection holes for spraying gas may be formed at the lower portion of the showerhead 555. The gas supply line 553 is connected to the showerhead 555. The gas supply line 553 connects the gas source 551 and the showerhead 555. The gas supplied from the gas source 551 is supplied into the internal space of the housing 520 through the gas supply line 553 and the showerhead 555. Accordingly, an atmosphere can be formed in the internal space. According to an example, the internal space may be created into a low-humidity atmosphere.

The shutter unit 570 opens and closes the entrances 521a and 522a. A plurality of shutter units 570 may be provided. According to an example, the shutter unit 570 may include a first shutter unit 571 and a second shutter unit 572. Hereafter, the description will be based on the first shutter unit 571.

The first shutter unit 571 includes a first shutter 5711 and a first shutter driving unit 5713. The first shutter 5711 covers the first entrance 521a. The first shutter 5711 opens and closes the first entrance 521a. The first shutter 5711 provided wider than the first entrance 521a. Accordingly, the first entrance 521a is sealed by the first shutter 5711. The first shutter 5711 is composed of a first inner shutter 5711a and a first outer shutter 5711b.

The first inner shutter 5711a is installed adjacent to the first entrance 521a. The first inner shutter 5711a may be provided in a size corresponding to the first entrance 521a. The first inner shutter 5711a may be provided in a rectangular ring shape. Accordingly, a first opening 5712 having a rectangular shape may be formed in the central area of the first inner shutter 5711a. The first opening 5712 may be provided in a size that allows only substrates W and the transfer robot 352 to enter through the supporting plates 531-2 and 531-3.

The first outer shutter 5711b is installed outside the first inner shutter 5711a. The first outer shutter 5711b may be provided in a size corresponding to the first opening 5712. The first outer shutter 5711b may be provided in a plate shape. Accordingly, the first outer shutter 5711b can seal the first opening 5712.

The first shutter driving unit 5713 drives the first inner shutter 5711a and the first outer shutter 5711b. The first shutter driving unit 5713 drives the first inner shutter 5711a and the first outer shutter 5711b such that they move in the vertical direction. According to an example, the first shutter driving unit 5713 may include a cover 5713a and a motor (not shown), and the motor may be disposed in the cover 5713a.

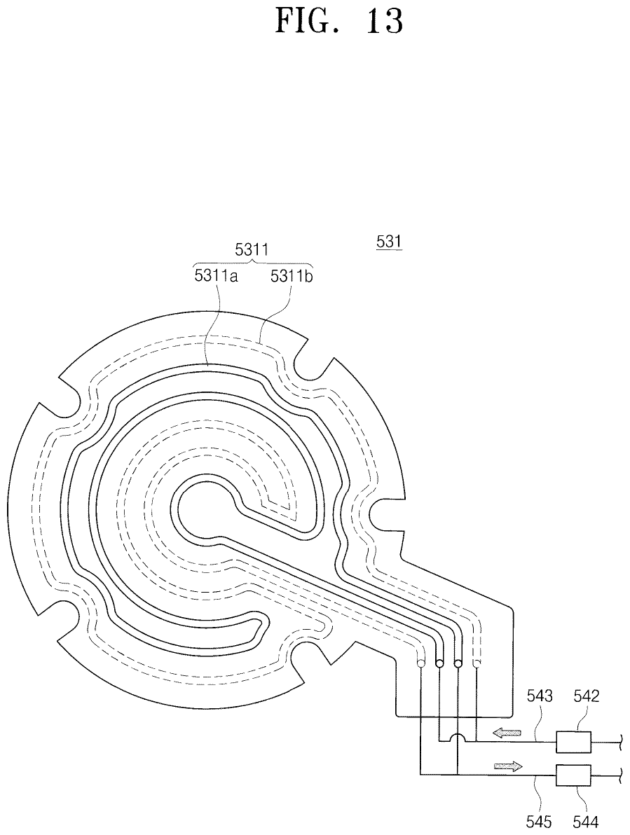

FIG. 12 and FIG. 13 are views showing a state in which a first entrance is opened and closed by a combination of a first outer shutter and a first inner shutter of the buffer chamber of FIG. 13.

Referring to FIG. 12 and FIG. 13, the first shutter driving unit 5713 can independently drive the first inner shutter 5711a and the first outer shutter 5711b. The first shutter driving unit 5713 can open and close only a portion of the first entrance 521a. The first shutter driving unit 5713 can open and close a portion of the first entrance 521a corresponding to any one of a plurality of supporting plates 531-1, 531-2, 531-3, and 531-4. The term “corresponding” means that only the transfer robot 352 can enter the supporting plate 531 intended for the loading or unloading of a substrate W. According to an example, the first inner shutter 5711a and the first outer shutter 5711b move down simultaneously, thereby being able to open a portion of the first entrance 521a so that the transfer robot 352 enters only the supporting plate 531-4. Alternatively, the first inner shutter 5711a may remain fixed, the first outer shutter 5711b may move down, and a portion of the first entrance may be opened so that the transfer robot 352 enters only the supporting plate 531-3. By opening only a portion of the first entrance 521a, the change in the atmosphere of the buffer chamber 500 can be minimized.

The first shutter driving unit 5713 is adjacent to the first sidewall 521. The first shutter driving unit 5713 may be installed on the first sidewall 521. The first shutter driving unit 5713 may be positioned on a side of the first shutter 5711. By positioning the first shutter 5711 and the first shutter driving unit 5713 adjacent to each other, the structure of the buffer chamber 500 can be simplified. Further, because the first shutter driving unit 5713 is installed on the first sidewall 521, the buffer chambers 500 can be stacked on each other.

The second shutter unit 572 is provided on the second sidewall 522. Since the second shutter unit 572 and the first shutter unit 571 are substantially the same, the second shutter unit 572 is no longer described.

The exhaust unit 590 exhausts the internal space. The exhaust unit 590 includes an exhaust line 591 connected to the internal space. The exhaust line 591 may be connected to the internal space through an exhaust hole formed on a side of the buffer chamber 500.

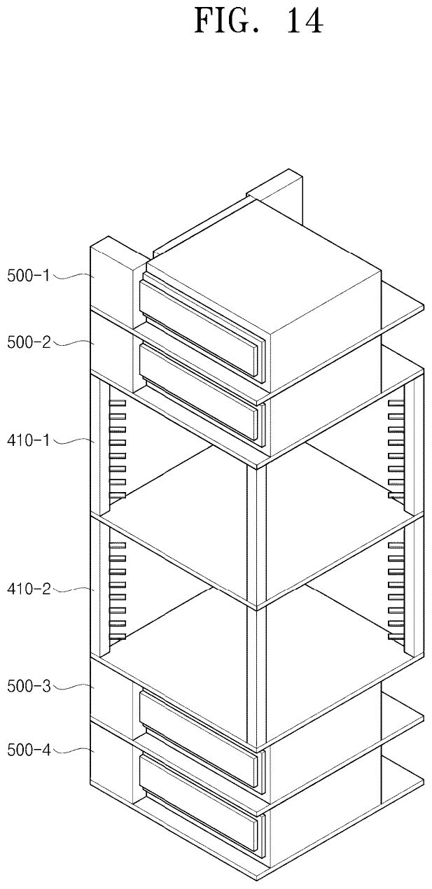

FIG. 14 is a perspective view showing a state in which plurality of buffer chambers and a plurality of buffer units are stacked on each other. Referring to FIG. 14, a plurality of buffer chambers 500 may be provided. According to an example, four buffer chambers 500 may be provided. A plurality of buffer units 410 may be provided. According to an embodiment, two buffer units 410 may be provided. The buffer unit 410 and the buffer chamber 500 may be stacked. The buffer unit 410 and the buffer chamber 500 may be stacked together. According to an example, two buffer chambers 500-1 and 500-2, two buffer units 410-1 and 410-2, and two buffer chambers 500-3 and 500-4 may be stacked in this order.

A controller (not shown) controls the apparatus 10 for treating substrates of the present disclosure. The configuration, storage, and management of the controller can be realized in the form of hardware, software, or a combination of hardware and software. File data and/or software that constitute the controller can be stored in volatile or non-volatile storage devices such as Read Only Memory (ROM), regardless of whether it is erasable or rewritable, or, for example, in memories such as Random Access Memory (RAM), memory chips, devices, or integrated circuits, or, for example, in storage media that can be optically or magnetically recorded and can be read by machines (for example, a computer) such as Compact Disk (CD), Digital Versatile Disc (DVD), magnetic discs, or magnetic tapes.

The rear buffer 400b temporarily keeps substrates W that have undergone a process before they are moved to the exposure module 700. The rear buffer 400b is generally the same as the front buffer 400a.

The following describes a process in which a substrate accommodated in a container F is transferred to the processing module in the apparatus 10 for treating substrates of the present disclosure. The components performing the steps of the process can be driven by the controller. The controller can independently control the components.

The container F is positioned on the load port 110 and the container F is opened. The index robot 132 unloads the substrate W from the container F and loads the substrate W into the buffer unit 410. The buffer robot 450 then unloads the substrate W from the buffer unit 410. The buffer robot 450 moves upward or downward with the substrate W in the third direction 16. The buffer robot 450 moves to the height corresponding to the buffer chamber 500 into which the substrate W is to be loaded. The second shutter driving unit 5723 drives the second shutter 5721. Accordingly, the second entrance 522a is opened and the buffer robot 450 loads the substrate W into the buffer chamber 500. Thereafter, the transfer robot 352 moves to the buffer chamber 500. The first shutter driving unit 5713 drives the first shutter 5711. Accordingly, the first entrance 521a is opened and the transfer robot 352 unloads the substrate W from the buffer chamber 500. Thereafter, the transfer robot 352 loads the substrate W into the liquid processing chamber 360 or the thermal processing chamber 320, in which the substrate W is processed.

These processes described above can be performed sequentially or simultaneously.

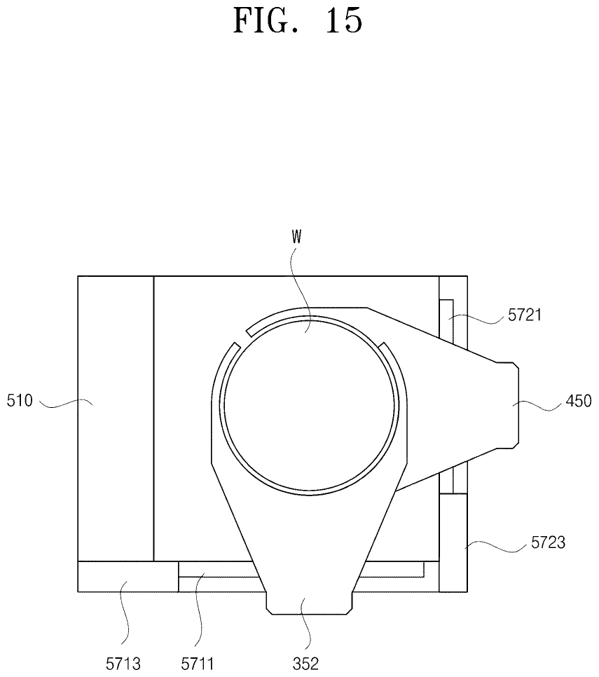

Accordingly, both the first shutter 5711 and the second shutter 5721 are opened, and, as shown in FIG. 15, the transfer robot 352 and the buffer robot 450 can simultaneously load or unload the substrate W into or from the buffer chamber 500.

Since a metal-containing resist applied to a substrate W is vulnerable to moisture, it is necessary to maintain a low-humidity atmosphere around the substrate W. According to an embodiment of the present disclosure, the buffer chamber W is provided as a sealed structure, so the atmosphere in the internal space can be controlled. In particular, when low-humidity gas is supplied to the internal space, the internal space can be maintained at a low humidity.

Further, according to an embodiment of the present disclosure, even if the shutters 5711 and 5721 open the entrances 521a and 522a, the influx of moisture into the internal space can be minimized by opening only a portion of the entrances 521a and 522a, thereby being able to maximize the protection of a metal-containing resist.

Further, according to an embodiment of the present disclosure, since the shutter driving units 5713 and 5723 are installed on the sidewalls of the buffer chamber 500, the structure of the buffer chamber 500 can be simplified. Accordingly, a plurality of buffer chambers 500 can be stacked.

Further, according to an embodiment of the present disclosure, even though the buffer chamber 500 is provided as a sealed structure, since shutter units are provided on a plurality of sidewalls, and the plurality of shutters are independently driven by a plurality of shutter driving units, a plurality of robots 352 and 450 can simultaneously enter the buffer chamber 500, thereby being able to improve the transfer efficiency of substrates W.

In the example described above, it was exemplified that only the buffer robot 450 is provided. However, the present disclosure is not limited thereto, and the buffer robot 450 may be a first buffer robot 450-1, a second buffer robot 450-2 may be further provided. The first buffer robot 450-1 and the second buffer robot 450-2 may be positioned at opposite sides with the buffer unit 410 therebetween. The first buffer robot 450-1 and the second buffer robot 450-2 face each other. According to an example, the first buffer robot 450-1 may be provided adjacent to the liquid processing chamber 360 and the second buffer robot 450-2 may be provided adjacent to the thermal processing chamber 320. In this case, second sidewalls 522 of the first buffer chamber 500-1 and the second buffer chamber 500-2 may be sidewalls facing the first buffer robot 450-1, and second sidewalls 522 of the third buffer chamber 500-3 and the fourth buffer chamber 500-4 may be sidewalls facing the second buffer robot 450-2.

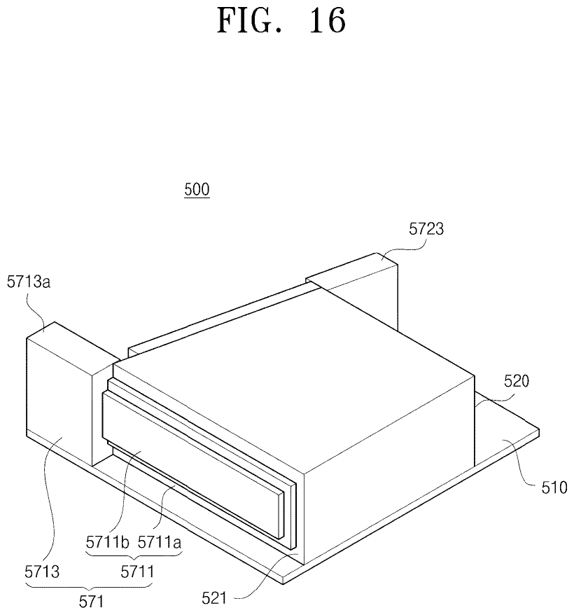

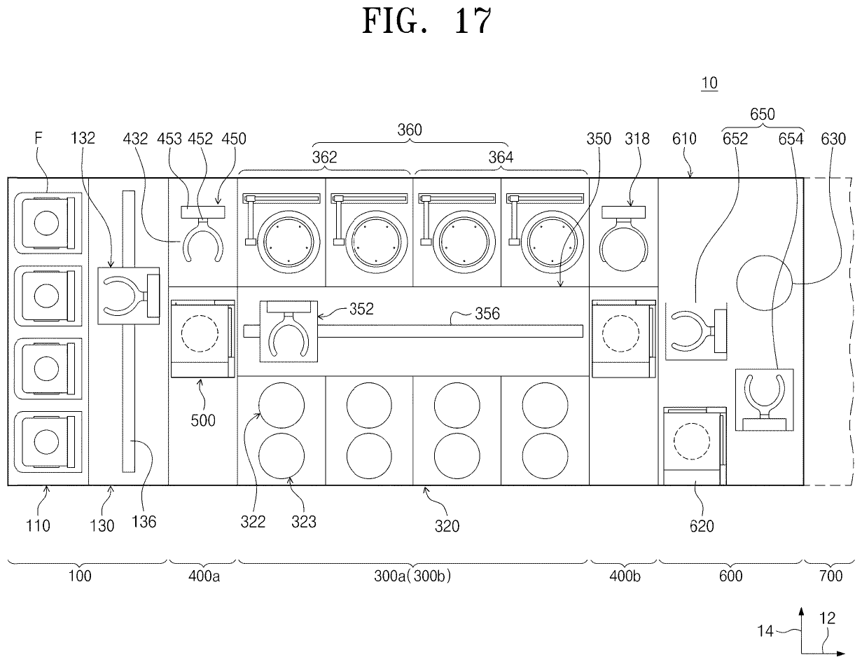

Further, in the example described above, the angle formed by the first sidewall 521 and the second sidewall 522 was exemplified as a right angle. However, the present disclosure is not limited thereto and, as shown in FIG. 16, the angle formed by the first sidewall 521 and the second sidewall 522 may not be a right angle. In this case, the movement direction of the hand 451 may be appropriately adjusted in accordance with the formed angle.

Further, in the example described above, the buffer unit 410 and buffer robot 450 are provided, and it was exemplified that the second sidewall 522 is a wall facing the buffer robot 450. However, the present disclosure is not limited thereto, and the buffer unit 410 and buffer robot 450 may not be provided, and the second sidewall 522 may be a wall facing the index robot 132.

Further, in the example described above, the shutter units 571 and 572 are provided only on the two sidewalls 521 and 522 of the housing 520. However, the present disclosure is not limited thereto, and separate shutter units may also be provided on the third sidewall 523 and/or the fourth sidewall 524.

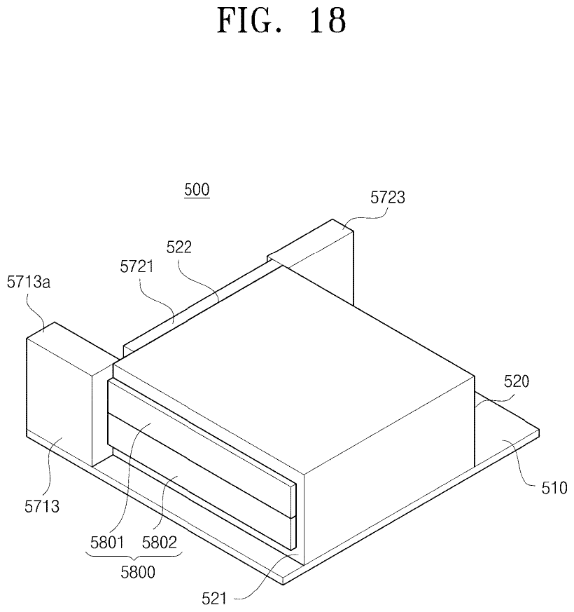

Further, in the example described above, the buffer chamber 500 is provided only at the front buffer 400a. However, the present disclosure is not limited thereto, and as shown in FIG. 17, it may also be provided at the rear buffer 400b and/or the interface module 600. When it is provided at the rear buffer 400b, it may be stacked with the buffer unit 410 provided at the rear buffer 400b. The first sidewall 521 and the second sidewall 522 may be determined on the basis of the direction in which the transfer robot 352 and the buffer robot 450 approach. Further, when it is provided on the interface module 600, it may be stacked with the auxiliary process chamber 620 and/or the interface buffer 630. The first sidewall 521 and the second sidewall 522 may be determined on the basis of the direction in which the first robot 652 and second robot 654 approach.

Further, in the example described above, it was exemplified that the shutter is composed of an inner shutter and an outer shutter. However, the present disclosure is not limited thereto, and as shown in FIG. 18, the shutter 5800 may be composed of an upper shutter 5801 and a lower shutter 5802. In this case, the upper shutter 5801 and the lower shutter 5802 overlap each other when viewed from above, and the upper shutter 5801 is provided above the lower shutter 5802.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An apparatus of processing substrates, comprising:
a first module;
a second module; and
a buffer chamber disposed between the first module and the second module and temporarily keeping substrates that are transferred between the first module and the second module,
wherein the buffer chamber includes:
a housing providing an internal space;
a supporting unit having a supporting plate, on which a substrate is placed, in the internal space;
a first shutter unit formed on a first sidewall of the housing, and opening and closing a first entrance for loading and unloading substrates; and
a gas supply unit supplying gas into the internal space.

2. The apparatus of claim 1, wherein the first module is an index module,
the second module is a processing module,
the index module includes:
a load port on which a container accommodating substrates is placed; and
an index robot transferring substrates from a container placed on the load port to the processing module, and storing substrates processed in the processing module into the container placed on the load port, and
the second module includes:
a process chamber processing substrates; and
a transfer chamber having a transfer robot that loads substrates into the process chamber or unloads substrates from the process chamber.

3. The apparatus of claim 2, wherein the buffer chamber further includes a cooling unit that cools a substrate placed on the supporting plate.

4. The apparatus of claim 3, wherein the first shutter unit includes:
a first shutter opening and closing the first entrance; and
a first shutter actuator actuating the first shutter, and
the first shutter actuator operates to open and close only a partial area of the first entrance.

5. The apparatus of claim 4, wherein the first shutter unit includes:
a first inner shutter; and
a first outer shutter,
the first inner shutter is provided in a ring shape such that a first opening is formed in a center area,
the first outer shutter is installed to seal the first opening, and
the first shutter actuator independently drives the first outer shutter and the first inner shutter.

6. The apparatus of claim 5, wherein the first shutter actuator is installed adjacent to the first sidewall,
a plurality of buffer chambers is stacked, and
the apparatus further includes a buffer robot that transfers substrates among the buffer chambers.

7. The apparatus of claim 6, wherein the buffer chamber further includes a second shutter unit formed on a second sidewall of the housing, and opening and closing a second entrance for loading and unloading substrates,
the second entrance faces the transfer robot, and
the first entrance faces the buffer robot.

8. The apparatus of claim 7, wherein the buffer chamber is a first buffer chamber,
the buffer robot is a first buffer robot,
the apparatus further includes:
second buffer chambers;
a second buffer robot transferring substrates among the second buffer chambers; and
an interface module positioned at the rear side of the processing module and connecting the apparatus to an external device, and
the second buffer chambers are positioned at the rear side of the processing module and the interface module.

9. The apparatus of claim 8, wherein the gas supply unit includes a showerhead spraying the gas to the internal space.

10. The apparatus of claim 9, wherein the gas is a low-humidity gas or a gas not containing moisture.

11. A buffer chamber for temporarily storing substrates, the buffer chamber comprising:
a housing providing an internal space;
a supporting unit having a supporting plate on which a substrate is placed in the internal space;
a first shutter unit formed on a first sidewall of the housing, and opening and closing a first entrance for loading and unloading substrates; and
a gas supply unit supplying gas into an internal space.

12. The buffer chamber of claim 11, further comprising a cooling unit cooling a substrate on the supporting plate.

13. The buffer chamber of claim 12, wherein the first shutter unit includes:
a first shutter opening and closing the first entrance; and
a first shutter actuator actuating the first shutter, and
the first shutter actuator operates to open and close only an area corresponding to the supporting plate of the first entrance.

14. The buffer chamber of claim 13, wherein the first shutter unit includes:
a first inner shutter; and
a first outer shutter,
the first inner shutter is provided in a ring shape such that a first opening is formed in a center area,
the first outer shutter is installed to seal the first opening, and
the first shutter actuator independently drives the first outer shutter and the first inner shutter.

15. The buffer chamber of claim 14, wherein the first shutter actuator is installed adjacent to the first sidewall.

16. The buffer chamber of claim 15, wherein the buffer chamber further includes a second shutter unit formed on a second sidewall of the housing, and opening and closing a second entrance for loading and unloading substrates,

17. Substrate processing apparatus, comprising:
an index module unloading substrates from a container accommodating substrates or loading substrates into the container;
a processing module processing substrates; and
a buffer chamber temporarily storing substrates,
wherein the index module includes:
a load port on which a container accommodating substrates is placed; and
an index robot transferring substrates from a container placed on the load port to the processing module, and storing substrates processed in the processing module into the container placed on the load port,
wherein the processing module includes:
a process chamber processing substrates; and
a transfer chamber having a transfer robot that loads substrates into the process chamber or unloads substrates from the process chamber,
wherein the buffer chamber further includes a cooling unit cooling a substrate on the supporting plate,
wherein the first shutter unit includes:
a first shutter opening and closing the first entrance; and
a first shutter actuator actuating the first shutter, and
the first shutter actuator is installed adjacent to the first sidewall, wherein a plurality of buffer chambers is stacked, and
further includes a second shutter unit formed on a second sidewall of the housing, and opening and closing a second entrance for loading and unloading substrates,
wherein the apparatus further includes a buffer robot that transfers substrates among the buffer chambers,
the second entrance faces the transfer robot, and
the first entrance faces the buffer robot.

18. The apparatus of claim 17, wherein the first shutter unit includes:
a first inner shutter; and
a first outer shutter,
the first inner shutter is provided in a rectangular ring shape such that a first opening is formed in a center area,
the first outer shutter is installed to seal the first opening, and
the first shutter actuator independently drives the first outer shutter and the first inner shutter.

19. The apparatus of claim 18, wherein the buffer chamber is a first buffer chamber,
the buffer robot is a first buffer robot,
the apparatus further includes:
second buffer chambers;
a second buffer robot transferring substrates among the second buffer chambers; and
an interface module positioned at the rear side of the processing module, and connecting the processing module to an exposure module performing exposure processing on substrates, and
the second buffer chambers are positioned at the rear side of the processing module and the interface module.

20. The apparatus of claim 19, wherein the gas is a low-humidity gas or a gas not containing moisture, and
the processing chamber includes:
a first processing chamber coating a metal-containing resist onto substrates; and
a second chamber performing thermal processing on substrates coated with the metal-containing resist.
